(19) United States
(12) Patent Application Publication
(10) Pub. No.: US 2016/0020199 A1
(43) Pub. Date: Jan. 21, 2016

(54) SEMICONDUCTOR STRUCTURE WITH SPARE CELL REGION

(71) Applicant: Mediatek Inc., Hsin-Chu (TW)

(72) Inventors: Chih-Hsin Fu, Hsinchu City (TW); Yu-Tung Chang, Hsinchu City (TW)

(21) Appl. No.: 14/331,233

(22) Filed: Jul. 15, 2014

(51) Int. Cl. H01L 27/02; H01L 23/528

(52) U.S. Cl. CPC H01L 27/0207; H01L 23/528

(57) ABSTRACT

A semiconductor structure includes a first spare cell region, a first conductive line and a second conductive line. The first spare cell region has a plurality of spare cells. The first conductive line is coupled between a first reference voltage and the plurality of spare cells, and is arranged for providing the first reference voltage to the plurality of spare cells of the first spare cell region. The second conductive line is coupled to a plurality of spare cells, and is arranged for providing a second reference voltage to the plurality of spare cells of the first spare cell region.

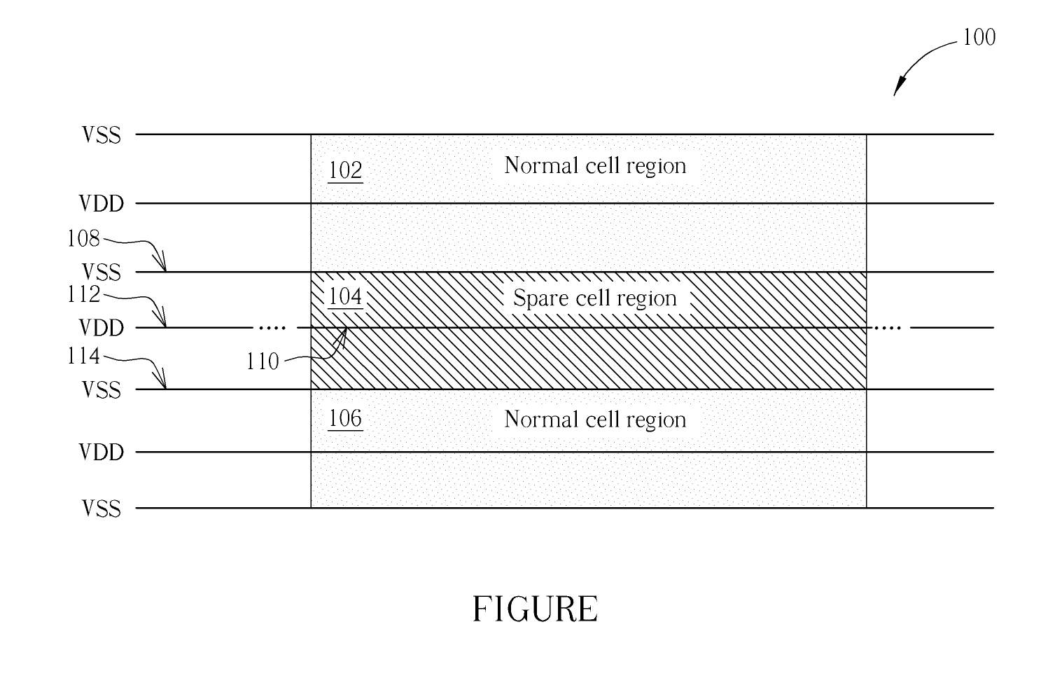

### BACKGROUND

The present invention relates generally to semiconductor structures, and more particularly, to a semiconductor structure with spare cell region(s) for reducing leakage power.

A standard integrated circuit (IC) includes a great number of electronic devices, cells and circuit modules for carrying out certain functions required by design specifications. These devices, cells and circuit modules are typically constructed on a semiconductor substrate overlaid by a number of metal levels, where conductive patterns are deployed as an interconnection network. As well as these normally functioning electronic components, the IC also has spare or dummy cells that do not play an active role in the IC operation. While the spare cells maybe designed to carryout certain functions, they are not connected to the normally functioning electronic components according to the original circuit design of the IC, but can be selectively connected to the normally functioning electronic components during a revising or rerouting process of the IC. This process is often referred to as an Engineering Change Order (ECO) process, and the spare cells can be alternatively referred to as ECO cells.

The spare cells occupy approximately five to ten percent of the total cell count in a typical IC. Conventionally, the spare cells are always coupled to a power supply and ground, even though they are not connected to other electronic components in the IC. A significant amount of power may leak through the spare cells as a result. For an IC manufactured using 28 nm semiconductor process technology, the spare cells typically account for approximately ten to fifteen percent of leakage power. This power leakage problem becomes worse with advances in semiconductor process technology which cause the IC to shrink in size.

Thus, there is a major need in the field of IC design for a spare cell design that can reduce the leakage power of the IC.

### SUMMARY

One of the objectives of the present invention is to provide a semiconductor structure which is capable of mitigating/avoiding the leakage power induced by spare cells.

According to an aspect of the present invention, a semiconductor structure is disclosed. The semiconductor structure comprises a first spare cell region, a first conductive line and a second conductive line. The first spare cell region comprises a plurality of spare cells. The first conductive line is coupled between a first reference voltage and the plurality of spare cells, and is arranged for providing the first reference voltage to the plurality of spare cells of the first spare cell region. The second conductive line is coupled to a plurality of spare cells, and is arranged for providing a second reference voltage to the plurality of spare cells of the first spare cell region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The FIGURE is a layout diagram illustrating a semiconductor structure according to an exemplary embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is electrically connected to another device, that connection may be through a direct electrical connection, or through an indirect electrical connection via other devices and connections.

The FIGURE is a layout diagram illustrating a semiconductor structure 100 according to an exemplary embodiment of the present invention. The semiconductor structure 100 includes a plurality of normal cell regions 102 and 106, each having normal cells placed therein, wherein the normal cell regions 102 and 106 are both illustrated by blocks filled in with a dotted pattern. The normal cells perform certain predetermined functions in normal cases according to a designer's plan. Unlike the conventional design in which scattered spare cells are mixed together with the normally functioning cells for an Engineering Change Order (ECO) process, the exemplary embodiment is characterized by disposing the normal cells and the spare cells into two different regions (two long strips) for the convenience of power control. Details will be given in the following paragraphs.

In addition to the normal cell regions 102 and 106 which possess mainly normal cells for normal functions of the IC, the semiconductor structure 100 further includes a spare cell region 104 which possesses mainly spare cells, wherein the spare cell region 104 is illustrated by a block filled in with a slashed line pattern. Each of the spare cells of the spare cell region 104 includes one or more doped regions, and the doped regions are coupled together by via contacts and conductive patterns so that the spare cell can carry out certain predetermined functions. The normal cells of the normal cell regions 102 and 106 are commonly powered by a first voltage VSS and a second voltage VDD, while the spare cells of the spare cell region 104 are preset to be disconnected from the second voltage VDD by separating a conductive power line 110 from the second voltage VDD. Although the spare cells of the spare cell region 104 are not disconnected from the first voltage VSS since conductive power lines 108 and 114 are coupled between the first voltage VSS and the spare cells, the spare cells of the spare cell region 104 are deactivated by default until the conductive power line 110 is connected to a conductive power line 112 by a rerouting process, according to the needs of the ECO process.

The spare cells are prepared in case functional failures occur to the normal cells. According to the exemplary embodiment shown in the FIGURE, spare cells are gathered into the spare cell regions (only one spare cell region is shown in the FIGURE for simplicity) which are strip regions interweaved with the normal cell regions. In this way, all of the spare cell regions are able to be deactivated by default and the associated leakage power introduced by spare cells is therefore dramatically reduced. When the ECO process needs to be performed according to design requirements, the interweaved-layout scheme enables the possibility of quickly and simply repairing the functional mistakes of the normal cells by the rerouting process. As a result, the disclosed semiconductor structure with separated spare/normal cell regions is advantageous, as it can reduce leakage power as well as facilitate the ECO process.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor structure, comprising:
a first spare cell region, comprising a plurality of spare cells;
a first conductive line, coupled between a first reference voltage and the plurality of spare cells, arranged for providing the first reference voltage to the plurality of spare cells of the first spare cell region; and
a second conductive line, coupled to the plurality of spare cells, arranged for providing a second reference voltage to the plurality of spare cells of the first spare cell region;
wherein the second conductive line is selectively coupled to the second reference voltage; and when the second conductive line is not coupled to the second reference voltage, the first conductive line is coupled to the first reference voltage.

2. The semiconductor structure of claim 1, further comprising:
a plurality of normal cells, arranged for performing a plurality of predetermined functions;
wherein when each spare cell of the plurality of spare cells is utilized in an Engineering Change Order (ECO) process, the spare cell is selectively coupled to the normal cells to perform the predetermined functions.

3. (canceled)

4. The semiconductor structure of claim 1, further comprising:
a third conductive line coupled between the first reference voltage and the plurality of spare cells, arranged for providing the first reference voltage to the plurality of spare cells.

5. The semiconductor structure of claim 4, wherein the second conductive line is disposed between the first conductive line and the third conductive line, and the first spare cell region is located between the first conductive line and the third conductive line.

6. The semiconductor structure of claim 5, further comprising:
a normal cell region, comprising a plurality of normal cells which perform a plurality of predetermined functions; and
a second spare cell region, comprising a plurality of spare cells;
wherein each normal cell of the normal cell region is coupled to the first reference voltage and the second reference voltage, and the plurality of spare cells of the second spare cell region is coupled to the first reference voltage and selectively coupled to the second reference voltage.

7. The semiconductor structure of claim 6, wherein when each spare cell of the second spare cell region is utilized in an Engineering Change Order (ECO) process, the spare cell is selectively coupled to the second reference voltage to perform the predetermined functions.

8. The semiconductor structure of claim 7, wherein the normal cell region is disposed between the first spare cell region and the second spare cell region.

9. The semiconductor structure of claim 8, wherein each normal cell of the normal cell region is further coupled to the third reference voltage.

10. The semiconductor structure of claim 8, wherein each spare cell of the second spare cell region is further coupled to the first reference voltage.
